(19) United States
(12) Patent Application Publication
(10) Pub. No.: US 2016/0240724 A1
(43) Pub. Date: Aug. 18, 2016

(54) METHOD FOR PRODUCING A SOLAR CELL

(71) Applicant: INTERNATIONAL SOLAR ENERGY RESEARCH CENTER KONSTANZ E.V., Konstanz (DE)

(72) Inventors: Tim BOESCKE, Erfurt (DE); Daniel KANIA, Erfurt (DE)

(73) Assignee: ION BEAM SERVICES, Peynier (FR)

(21) Appl. No.: 15/024,879

(22) PCT Filed: Sep. 26, 2014
(86) PCT No.: PCT/EP2014/070613

§ 371 Date: Mar. 25, 2016

(30) Foreign Application Priority Data
Sep. 27, 2013 (DE) 10 2013 219 603.2

(51) Int. Cl. H01L 31/18; H01L 31/0216; H01L 31/0236; H01L 31/068

(52) U.S. Cl. CPC H01L 31/1864; H01L 31/1804; H01L 31/0684; H01L 31/02168; H01L 31/02363; H01L 31/1868

(57) ABSTRACT

The invention relates to a method for producing a solar cell (1) from crystalline semiconductor material. In a first surface (3a) of a semiconductor substrate (3), a first doping area (5) is formed by thermally diffusing a first dopant and in the second surface (3b) of the semiconductor substrate, a second doping area (7) is formed by implanting ions and thermally implanting a second dopant.

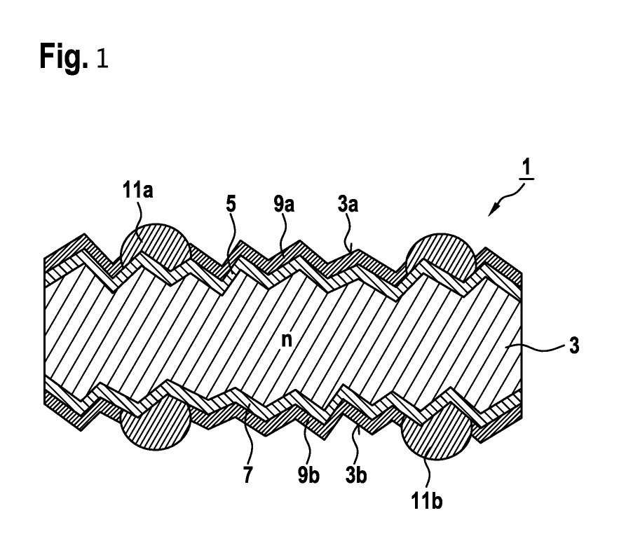

The invention concerns a method for producing a solar cell from crystalline semiconductor material, wherein in a first surface of a semiconductor substrate a first doping region is formed by thermal indiffusion of a first dopant and in the second surface of the semiconductor substrate a second doping region is formed with a second dopant

### STATE OF THE ART

Solar cells based on mono or polycrystalline semiconductor material, in particular silicon, constitute in spite of the development and the launching of the market of new generations of solar cells, such as thin film and organic solar cells, the largest portion, by far, of the electric energy recovered by photovoltaic conversion of energy. Crystalline silicon solar cells have also seen recently important new developments, among which the solar cells of the type aforementioned (especially the so-called n-PERT solar cells).

To increase the efficiency of industrial solar cells, the development of solar cells will be boosted with phosphorus and boron doped regions. A prominent example consists of bifacial n-type solar cells containing a boron doped emitter on the front side and a phosphorus doped Back Surface Field (BSF) on the rear side of the cell.

In particular if the doped regions are contacted with a screen print metallisation, it is desirable to adjust, for both dopants, doping profiles which contribute the various contacting behaviour of market standard metallisation pastes. If conventional diffusion processes are used, at least two high-temperature steps as well as additional steps for masking the diffusions are necessary, under those circumstances.

Said different requirements are rather strict as regards the process sequence since the diffusion constants of phosphorus and boron are practically the same. In an exemplary embodiment with two diffusion processes, the processes influence each other as they must be carried out sequentially.

If the phosphorus diffusion is performed before the boron diffusion, the thermal budget of the boron diffusion increases the depth of the phosphorus diffusion. In such a case, the phosphorus diffusion is deeper than the boron diffusion, exactly the contrary of the targeted design. If the phosphorus diffusion is carried out after the boron diffusion, the desired profile configuration can still be adjusted. Indeed, there is always the requirement to protect the boron emitter against the indiffusion of phosphorus. This can hardly be performed with a good industrial yield, in particular on textured solar cell front sides. A further shortcoming of the execution with two diffusion processes consists in high process complexity since several high temperature steps and caps are required.

Certain applications with reduced process complexity endeavour to carry out the diffusion of boron and phosphorus simultaneously in a high temperature step, so-called codiffusion. This may consist in diffusion from doping glasses or through ion implantation of both species, followed by a drive-in step. Apparently, both diffusion profiles have the same depth with this configuration.

### DISCLOSURE OF THE INVENTION

The invention enables to provide a method with the features of claim 1. Appropriate developments of the inventive concept are the object of the dependent claims.

The invention makes use of a hybrid configuration in which only the phosphorus-doped areas (or more generally: the second doping regions) are produced through ion implantation and the boron doping (or more generally: doping with the first dopant) on established applications such as diffusion out of the gas phase or out of doping glasses takes place. In the context of this conception, a cap acting primarily as a diffusion barrier layer is formed on the surface in which the second doping regions were reduced so as to prevent, or at least strongly reduce, any indiffusion of the first dopant.

The efficient application entails a series of problems whose solution, on the basis of the concept mentioned, finally leads to an optimal execution of the invention from this viewpoint. On the one hand, different doping profiles should be adjusted for both dopants, for the application already mentioned. Moreover, the problem is that the diffusion of the first dopant generates a doped area out of the gaseous phase or out of doping glasses on both sides of the semiconductor substrate, which explains that with solar cell constructions, which should have only one doping region with the first dopant on one of the surfaces, additional steps for preventing or eliminating undesirable doping areas.

The preferred process sequence of the present invention is characterised in that the thermal budget of the boron diffusion (or indiffusion of the first dopant) is used simultaneously for activating the implanted phosphorus region (or more generally: the dopant deposition layer of the second dopant).

A decisive feature is that a multifunctional cap is deposited on the phosphorus region after phosphorus ion implantation and before boron diffusion. The cap therefore exhibits the property of acting as an (in)diffusion barrier for the first dopant (for example boron) and thereby to prevent the layer from penetrating into the dopant deposition layer of the second dopant (special phosphorus).

In preferred embodiments, the cap has further properties/functions:
1. It acts as a diffusion barrier for oxygen.
2. It can act as an (out)diffusion barrier for phosphorus (or more generally the second dopant).
3. It acts as an electrical passivation layer on the second surface, especially the phosphorus-doped area.
4. It acts as an anti-reflection layer on the rear side of the solar cell, especially of a bifacial solar cell.

In embodiments of the method appropriate from today's point of view, the semiconductor material can be silicon, the first dopant can be an element from the group incorporating boron, indium, gallium, aluminium, in particular boron, and the second dopant can be an element from the group incorporating phosphorus, arsenic, antimony, in particular phosphorus. Especially, the dopant combination of boron and phosphorus, mentioned concretely above several times, is extremely important from a practical viewpoint, when considering ancient, efficiency-improving solar cell developments.

The suggested method can be carried out as a method for producing a solar cell, contacted on both sides, with a front side emitter or a solar cell with a rear side emitter or a MWT (Metal-Wrap-Through) solar cell or an IBC (Interdigital-Back-Contact) solar cell. Especially, the first doping region can be formed as an emitter region in the front side surface of a n-silicon substrate and the second doping region as a Back-Surface-Field in the rear side surface of the n-silicon substrate.

In a further embodiment, the doping profile of the second doping region is flatter with respect to the doping profile of the first doping region and/or is characterised by a higher surface concentration of the second dopant with respect to that of the first dopant. More especially, the method is designed in such a way that the formation of the first doping region encompasses applying on the first and optionally the second surfaces a glass containing the first dopant and preparing the first dopant in gaseous state in a process atmosphere.

A significant advantage of the invention consists in a vastly cost-optimised process sequence with only one high temperature step, with respect to the state of the art. This is achieved by using a diffusion barrier layer which enables the simultaneous use of a thermal indiffusion step for the first dopant for activation and the second dopant applied previously by ion implantation, without negative effects on the desired doping profile and offers many more advantages in appropriate execution, for example increased processing speed and reduced production costs with an oxygen-containing process atmosphere.

### DRAWING

The invention will be described below more in detail using an exemplary embodiment with reference to the diagrammatical drawings appended. The single FIGURE shows a diagrammatical cross-section illustration of the solar cell according to the invention.

### FORMS OF EMBODIMENT OF THE INVENTION

The single FIGURE shows diagrammatically in a cross-sectional representation a solar cell 1 with a crystalline silicon substrate 3 of n-type and of a respective pyramidal structured first (front side) surface 3a and second (rear side) surface 3b. In the first surface 3a, a first doping region (emitter region) 5 is formed by boron diffusion and in the second surface, a flat Back Surface Field 7 is formed as the second doping region by phosphorus implantation and subsequent curing/activation.

A thick silicon nitride layer or SiN-containing double layer 9a or 9b is systematically deposited on the first and second surfaces 3a, 3b as an anti-reflection layer. Consequently, the rear side silicon nitride layer 9B is a layer left after phosphorus implantation into the rear side surface 3b, but before a step of boron diffusion into the semiconductor substrate and after a thermal diffusion step. The anti-reflection layer can be completed by an additional partial layer made of oxide (for example silicon oxide) to improve the passivation properties of the layer, which is not shown in the FIGURE. The front side of the solar cells (first surface) 3a exhibits a front side metallisation 11a and the rear side of the solar cells (second surface) 3b a rear side metallisation 11b.

A sequence for the production of an n-type cell with a front side emitter and contacted on both sides is described. A variation is apparent to those skilled in the art to produce deviating solar cell types. The sequence of the production of this solar cell encompasses the process modules listed below in this order, whereas each process module consists of one or several process steps.

### Process Module 1: Texturing the Wafer

This process step may entail an industry standard texturing with subsequent cleaning. Optionally, the wafer can be planed on the back. To do so, several methods are provided by the state of the art and are not relevant for this invention.

### Process Module 2: Forming the Dopant Deposition Layer

(Phosphorus Implantation)

To do so, phosphorus is implanted into the cell rear side (for instance a dose between 0.5 and 7e15 1/cm² with an energy of 1-40 keV, preferred 1.5-4e15 1/cm², 10 keV). The layer resistance of the phosphorus layer is after curing (step 4) 10-300 Ohm/square; preferably 30-120 Ohm/square. In a further embodiment, the implantation can be selective so that the dose is higher under the metallisation region. Additionally, the implantation can be masked so that between the wafer edge and the phosphorus doping, a non-doped of 50-1000 μm width to provide an electric insulation between BSF and emitter.

The phosphorus implant is followed optimally by a cleaning of the wafer to remove undesired phosphorus residues and contamination. This takes place in a form of embodiment through wet-chemical process with one or more steps in water, thinned HF, HNO₃ or H₂O₂/HCl. In another exemplary, the cleaning can take place through a plasma process with hydrogen, oxygen and/or fluor-containing atmosphere.

After this process step, the phosphorus is in electrical inactive form in the bulk of the wafer, not at the wafer surface.

### Process Module 3: Generation of the Diffusion Barrier Layer

The cap (diffusion barrier layer) on the second substrate surface prevents the indiffusion of boron into said layer and is impermeable to oxygen. Moreover, it should provide good passivation as well as act as an anti-reflection layer when using the bifacial solar cell.

In the easiest embodiment, a pure SiN layer is used as a cap (refractive index n=I, 8-2, 2, preferably 1, 9-2). The thickness of the layer ranges between 1 nm and 250 nm, preferably 30-80 nm. Normally, the cap layer is deposited by a PECVD process with a chemical selected among one or several gases from the group containing SiH₄, N₂, NH₃, H₂, Ar. Alternatively, the cap can be applied with other methods, such as for instance LPCVD, APCVD or PVD.

For optimising all requirements, a layer stack can also be used so that an SiO₂, Al₂O₃, TiO or SiON layer can be inserted between silicon and SiN which can improve the electrical passivation properties. (0.5-50 nm, preferably 5 nm)

For optimising the barrier properties, a layer of amorphous or polycrystalline silicon can be inserted into the layer stack. (0.5-30 nm, preferably 20 nm).

### Process Module 4: Boron Diffusion and Simultaneously Phosphorus Activation

The boron diffusion is carried out through an oven process in which the wafer is first of all overlaid with boron glass in a boron-containing atmosphere. Usual precursors are then BBr₃ and BCl₃, additional process gases N₂ and O₂. The overlaying step is followed in-situ by a drive-in step in inert or oxygen-containing atmosphere. In the preferred variation, overlay and drive-in steps are carried out at least partially in oxygen-containing atmosphere so as to accelerate boron diffusion.

A further possibility consists in depositing a boron glass on the front side of the cell (for example through APCVD or PECVD) and subsequent drive-in in a separate process step.

The boron diffusion region is first and foremost characterised by the layer resistance which lies in particular between 30 and 200 Ohm/square, preferably 45-100 Ohm/square.

As represented above, the boron diffusion causes simultaneously curing and activation of the phosphorus-doped region. To do so, the phosphorus diffuses more deeply into the substrate, but more slowly than boron, when the process has a multifunctional layer.

The depths of the diffusion regions range between 30 nm and 2500 nm, preferably 400 and 100 nm, where the depth of boron is ideally greater than that of phosphorus.

### Process Module 5: Front Side Passivation

Different executions for passivation of boron emitters are known in the prior art. In so doing, passivation with a layer stack made of SiO₂/SiN or Al₂O₃/SiN is relevant. Said layer stack can be generated through a combination of PECVD and thermal oxidation processes. The exact configuration is not relevant for the invention.

Before passivation, the boron glass which may have formed in process module 4 must be removed from the front side as circumstances allow, which can be done with a diluted HF solution according to the state of the art.

### Process Module 6: Optional Additional Rear Side Passivation

If the diffusion barrier layer formed in process module 3 does not act simultaneously as electrical passivation of the cell rear side, it must be removed and replaced with an additional passivation layer. The cap can be removed through an extended HF step, together with the boron removal process in step 5.

A SiO/SiN or SiN layer can be used as passivation according to the state of the art.

### Process Module 7: Metallisation

Metallisation can use standard industry methods and is not important for the invention. The front side metallisation takes place usually with a silver grid. The rear side metallisation also takes place with a silver grid or a full-surface aluminium metallisation with local contacts which is produced for instance by laser ablation and PVD.

The order sequence of the doping process can be modified in a possible variation to this process in the case of rear side emitter cell (boron on rear side, phosphorus on front side). In such a case, boron can be implanted instead of phosphorus and the boron diffusion can be replaced with a phosphorus diffusion.

In a more specialised context known to those skilled in the art, further embodiments and variations can be contemplated on the basis of the method and device shown here purely by way of illustration.

1. A method for producing a solar cell (1) from crystalline semiconductor material, wherein in a first surface (3a) of a semiconductor substrate (3) a first doping region (5) is formed by thermal indiffusion of a first dopant and in the second surface (3b) of the semiconductor substrate a second doping region (7) is formed through ion implantation or thermal indiffusion of a second dopant,
whereas through the ion implantation of the second dopant, a dopant deposition layer is formed on or close to the second surface and on the second surface a diffusion barrier layer (9b) for preventing an outdiffusion of the second dopant is generated out of the second surface and then at least one thermal process step is carried to form the first and second doping regions.

2. The method of claim 1,
wherein the semiconductor material can be silicon, the first dopant can be an element from the group incorporating boron, indium, gallium, aluminium, in particular boron, and the second dopant can be an element from the group incorporating phosphorus, arsenic, antimony, in particular phosphorus.

3. The method of claim 1,
wherein the first doping region (5) is formed as the emitter region in the front side surface (3a) of an n-silicon substrate (3) and the second dopant region is formed as a back surface field (7) in the rear side surface (3b) of the n-silicon substrate.

4. A method according to claim 1,
whereas the doping profile of the second doping region (7) is flatter with respect to the doping profile of the first doping region (5) and/or is characterised by a higher surface concentration of the second dopant with respect to that of the first dopant.

5. A method according to claim 1,
whereas only one thermal process step is carried out to form the first and second doping regions (5; 7) whereby the thermal budget used for indiffusion of the first dopant causes the activation of the second dopant out of the previously formed dopant deposition layer, for which purpose the indiffusion of the first dopant is performed after forming the diffusion barrier layer (9b) on the second surface (3b) and whereas the diffusion barrier layer is formed as the indiffusion barrier to prevent any indiffusion of the first dopant into the second surface.

6. The method of claim 5,
whereas the diffusion barrier layer (9b) is formed at the same time as an oxygen diffusion barrier and the indiffusion of the first dopant is carried out at least in sections in an oxygen-containing atmosphere.

7. A method according to claim 1,
whereas the formation of the first doping region (5) encompasses applying on the first and optionally the second surfaces (3a;3b) a glass containing the first dopant and preparing the first dopant in gaseous state in a process atmosphere.

8. A method according to claim 1,
whereas the diffusion barrier layer (9b) on the second surface (3b) with a solar cell construction, in which the second surface forms the rear side of the solar cell (1), is left on the second surface as rear side passivation and/or rear side anti-reflection layer.

9. A method according to claim 1, designed as a method for producing of a solar cell (1) contacted on both sides with a front side emitter or a solar cell with a rear side emitter or a MWT (Metal-Wrap-Through) solar cell or an IBC (Interdigital-Back-Contact) solar cell.

10. A method according to claim 1,
whereas as a diffusion barrier layer (9b) an SiN layer, in particular with a refractive index of n=1, 8 . . . 2, 2, even more especially n=1, 9 . . . 2, 0, and in particular with a thickness between 1 and 250 nm, even more especially between 30 and 80 nm, is used.

11. The method of claim 10,
whereas a layer stack is used as a diffusion barrier layer, a layer stack which contains in addition to an SiN layer, an SiO₂—, Al₂O₃—, TiO— and/or SiON layer and with which the additional layer or additional layers has/have in particular a thickness in the region between 0.5 and 50 nm.

12. The method of claim 10,
whereas the diffusion barrier layer (9b) is generated by means of a PECVD-, LPCVD-, APCVD- or PVD-Process.
